(19) United States
(12) Patent Application Publication
(10) Pub. No.: US 2024/0098383 A1
(43) Pub. Date: Mar. 21, 2024

(54) IMAGE CAPTURING APPARATUS, METHOD OF CONTROLLING THEREOF, AND NON-TRANSITORY COMPUTER-READABLE MEDIUM

(71) Applicant: CANON KABUSHIKI KAISHA, Tokyo (JP)

(72) Inventor: AIHIKO NUMATA, Tokyo (JP)

(21) Appl. No.: 18/467,493

(22) Filed: Sep. 14, 2023

(30) Foreign Application Priority Data
Sep. 16, 2022 (JP) 2022-148405

(51) Int. Cl. H04N 25/704; G02B 7/04; H04N 25/78

(52) U.S. Cl. CPC H04N 25/704; G02B 7/04; H04N 25/78

(57) ABSTRACT

An apparatus is provided with a sensor including a plurality of pixels that are arrayed two-dimensionally, at least a part of the plurality of pixels being a phase-difference detection pixel that include a first conversion unit and a second conversion unit for performing phase-difference AF. A driving mechanism changes an angle of an image plane of the sensor relative to a main plane of an optical system. A readout unit reads out signals obtained in the first conversion unit and the second conversion unit in an order corresponding to the angle.

### BACKGROUND

### Technical Field

The aspect of the embodiments relates to an image capturing apparatus, a method of controlling thereof, and a non-transitory computer-readable medium.

### Description of the Related Art

In the case of a camera that includes a telephoto lens with a bright f-number, the depth of field is generally shallow. Therefore, in a case where a camera that includes such a lens is used to perform shooting from a diagonal direction (a non-orthogonal direction) relative to a subject plane while AF is functioning, the obtained image is in focus only in the vicinity of the center and is out of focus in a region other than the vicinity of the center. If the technique so-called tilt shooting, in which the optical axis of the lens is inclined relative to a solid-state image sensor, is used under the same circumstance, the in-focus range can be expanded.

Japanese Patent Laid-Open No. 2021-76777 suggests an image capturing apparatus that, in order to realize high-speed focusing during tilt shooting, uses the technique of so-called image-plane phase-difference AF with use of a solid-state image sensor that includes phase-difference detection pixels.

### SUMMARY

According to an embodiment of the disclosure, an apparatus is provided with a sensor including a plurality of pixels that are arrayed two-dimensionally, at least a part of the plurality of pixels being a phase-difference detection pixel that include a first conversion unit and a second conversion unit for performing phase-difference AF, the apparatus comprising: a driving mechanism configured to change an angle of an image plane of the sensor relative to a main plane of an optical system; and a readout unit configured to read out signals obtained in the first conversion unit and the second conversion unit in an order corresponding to the angle.

According to another embodiment of the disclosure, a method of controlling an apparatus provided with a sensor including a plurality of pixels that are arrayed two-dimensionally, at least a part of the plurality of pixels being a phase-difference detection pixel that include a first conversion unit and a second conversion unit for performing phase-difference AF and a driving mechanism configured to change an angle of an image plane of the sensor relative to a main plane of an optical system comprises reading out signals obtained in the first conversion unit and the second conversion unit in an order corresponding to the angle.

According to an embodiment of the disclosure, a non-transitory computer-readable medium stores one or more programs which, when executed by a computer comprising one or more processors and one or more memories, cause the computer to control an apparatus provided with a sensor including a plurality of pixels that are arrayed two-dimensionally, at least a part of the plurality of pixels being a phase-difference detection pixel that include a first conversion unit and a second conversion unit for performing phase-difference AF and a driving mechanism configured to change an angle of an image plane of the sensor relative to a main plane of an optical system, wherein the one or more programs further cause the computer to read out signals obtained in the first conversion unit and the second conversion unit in an order corresponding to the angle.

Further features of the disclosure will become apparent from the following description of exemplary embodiments (with reference to the attached drawings).

### BRIEF DESCRIPTION OF THE DRAWINGS

FIG. 1 is a block diagram showing a configuration of an image capturing apparatus according to one embodiment.

FIG. 2 is a diagram for describing the principle of tilt shooting.

FIG. 3 is a diagram showing an array of pixels in a solid-state image sensor.

FIG. 4 is a diagram showing a structure of a phase-difference detection pixel in the solid-state image sensor.

FIGS. 5A to 5C are diagrams showing light beams that enter a phase-difference detection pixel when the tilt angle is small.

FIGS. 6A to 6C are diagrams showing light beams that enter a phase-difference detection pixel when the tilt angle is large.

FIG. 7 is a diagram showing the relationships between the tilt angle and the sensitivities of photoelectric conversion units.

FIG. 8 is an equivalent circuit diagram of a phase-difference detection pixel.

FIG. 9 is a diagram showing a timing chart of readout of pixel signals from a phase-difference detection pixel.

FIGS. 10A to 10C are diagrams showing a structure of a phase-difference detection pixel of a solid-state image sensor according to one embodiment.

FIGS. 11A to 11C are diagrams showing light beams that enter a phase-difference detection pixel when the tilt angle is small.

FIGS. 12A to 12C are diagrams showing light beams that enter a phase-difference detection pixel when the tilt angle is large.

FIGS. 13A to 13C are diagrams showing light beams that enter a phase-difference detection pixel when the tilt angle is small.

FIGS. 14A to 14C are diagrams showing light beams that enter a phase-difference detection pixel when the tilt angle is large.

FIG. 15 is a configuration diagram of a surveillance system according to one embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to a disclosure that requires all such features, and multiple such features may be combined as appropriate. Furthermore, in the attached drawings, the same reference numerals are given to the same or similar configurations, and redundant description thereof is omitted.

In a case where focusing is performed during tilt shooting with use of the image-plane phase-difference AF on the image capturing apparatus disclosed in Japanese Patent Laid-Open No. 2021-76777, a sensitivity difference arises between a plurality of photoelectric conversion units depending on a tilt angle. As a result, the accuracy of ranging in phase-difference detection pixels decreases, the accuracy of in-focus shooting decreases, and the speed of focusing slows down.

One embodiment of the disclosure can suppress a decrease in the accuracy of ranging in an image capturing apparatus that performs tilt shooting with use of a solid-state image sensor that includes phase-difference detection pixels.

### First Embodiment

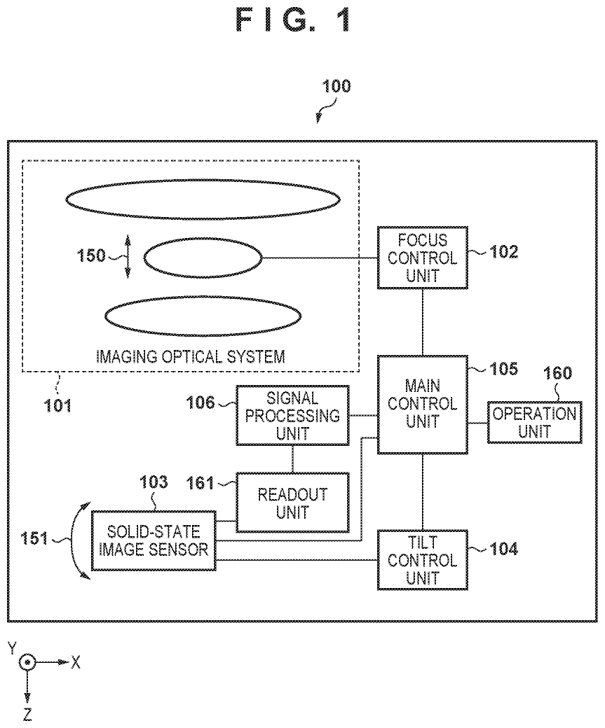

FIG. 1 shows a configuration of an image capturing apparatus according to a first embodiment. As shown in FIG. 1, an image capturing apparatus 100 includes an imaging optical system 101, a focus control unit 102, a solid-state image sensor 103, a tilt control unit 104, a main control unit 105, a signal processing unit 106, an operation unit 160, and a readout unit 161. Note that although the image capturing apparatus 100 also includes an operation unit that is intended for a user to input various types of instructions, a recording unit that records captured images into a storage medium, a display unit that displays captured images, and so forth, they are omitted as they are not the main points of the disclosure of the present application.

The main control unit 105 is composed of a CPU, a ROM that stores a program executed by the CPU, and a RAM that is used by the CPU as a working area. The main control unit 105 obtains an instruction from the user via the operation unit 160. Then, the main control unit 105 controls the entire apparatus by controlling the focus control unit 102, solid-state image sensor 103, tilt control unit 104, and signal processing unit 106.

### <Focus Control>

The imaging optical system 101 is composed of a plurality of lenses. Under control of the control unit 105, the focus control unit 102 causes a focus lens inside the imaging optical system 101 to move along a Z-axis indicated by an arrow 150 by driving a non-illustrated driving mechanism, such as a stepper motor. In this way, the focus control unit 102 can adjust the focus position of the imaging optical system 101.

### <Tilt Control>

The solid-state image sensor 103 is axially supported in such a manner that it is rotatable on an X-Z plane (an arrow 151 shown in the figure) in order to enable the angle of tilt relative to the optical axis direction to be changed. Under control of the control unit 105, the tilt control unit 104 can change the angle of an image plane of the solid-state image sensor 103 relative to a main plane of the imaging optical system 101 (a later-described tilt angle) by driving a non-illustrated driving mechanism, such as a stepper motor. It is assumed that this tilt angle is set by the user operating the operation unit 160.

### <Tilt Control Mechanism of Solid-State Image Sensor>

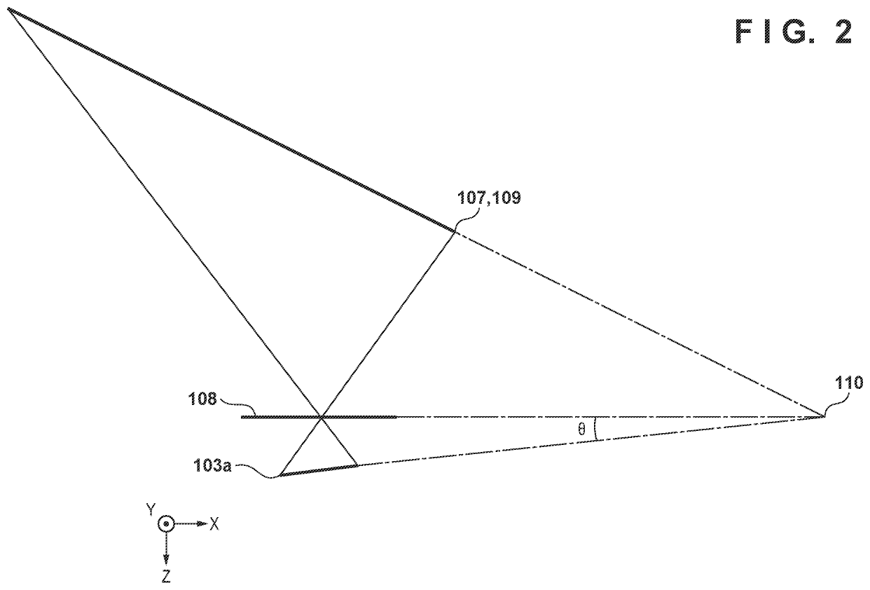

The following describes the relationship among the subject plane, the lens, and the image plane of the solid-state image sensor in tilt shooting with reference to FIG. 2. Reference sign 103a shown in the figure represents the image plane of the solid-state image sensor 103. Also, reference sign 108 represents the main plane of the imaging optical system 101 (in a case where the imaging optical system 101 is deemed as a single lens, a plane represented by this lens). Reference sign 107 represents a focus plane on which a subject 109 is brought into focus in tilt shooting.

In tilt shooting, according to the Scheimpflug principle, the image plane 103a, the main plane 108 of the imaging optical system 101, and the subject plane 107 intersect at a single point 110 that extends in the Y-axis direction. Therefore, the subject plane 107 is inclined relative to the main plane 108 of the imaging optical system 101. That is to say, in tilt shooting, causing the focus plane 107 to coincide with the subject 109 that is inclined relative to the main plane 108 of the imaging optical system 101 enables image capture in which a wide range of the subject 109 is in focus. The angle θ formed by the image plane 103a of the solid-state image sensor 103 and the main plane 108 of the imaging optical system 101 is called a tilt angle.

### <Solid-State Image Sensor>

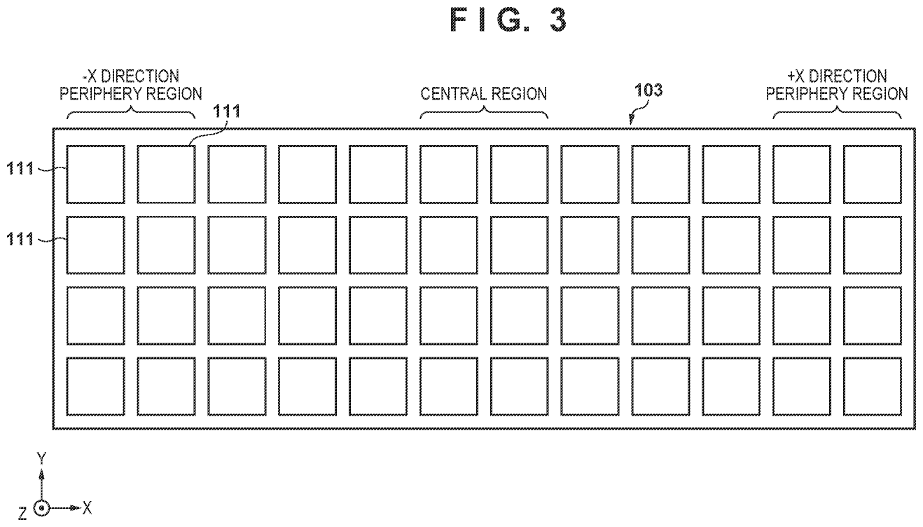

FIG. 3 shows a structure of the solid-state image sensor 103 according to an embodiment. A plurality of pixels are arrayed two-dimensionally in the solid-state image sensor 103, and a pixel group including at least a part of the plurality of pixels represents phase-difference detection pixels 111. AF that uses such phase-difference detection pixels are generally called image-plane phase-difference AF. FIG. 3 shows an example in which the solid-state image sensor 103 includes 12×4 pixels that are arrayed two-dimensionally, and all of the pixels are phase-difference detection pixels 111. Note that the number of pixels shown in the figure is intended to facilitate the understanding, and no particular restriction is placed on this number.

### <Phase-Difference Detection Pixels>

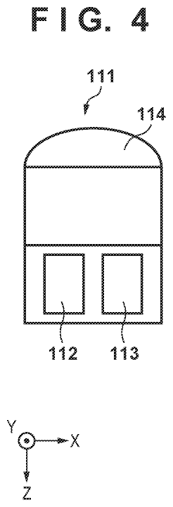

FIG. 4 is a diagram for describing a structure of one phase-difference detection pixel 111. The phase-difference detection pixel 111 includes a first photoelectric conversion unit 112 located on the left side (—X direction), a second photoelectric conversion unit 113 located on the right side (+X direction), and a microlens 114. Furthermore, although now illustrated, it also includes wiring for driving pixel circuits. In addition, it may include a color filter for detecting a color signal.

The arrangement is such that, due to the microlens 114, an exit pupil 120 of the imaging optical system 101 and the first photoelectric conversion unit 112 and the second photoelectric conversion unit 113 are placed in a conjugate positional relationship. As a result, a light beam that has mainly passed through the right half of the imaging optical system 101 is directed to the first photoelectric conversion unit 112. Also, a light beam that has mainly passed through the left half of the imaging optical system 101 is directed to the second photoelectric conversion unit 113. Thus, an amount of displacement of the subject from the focus position can be obtained by detecting an amount of image displacement between a first image, which has been generated from pixel signals obtained by the first photoelectric conversion units 112 that are respectively included in the plurality of phase-difference detection pixels 111, and a second image, which has been generated from pixel signals obtained by the second photoelectric conversion units 113 that are respectively included therein.

<Sensitivity Difference among Photoelectric Conversion Units>

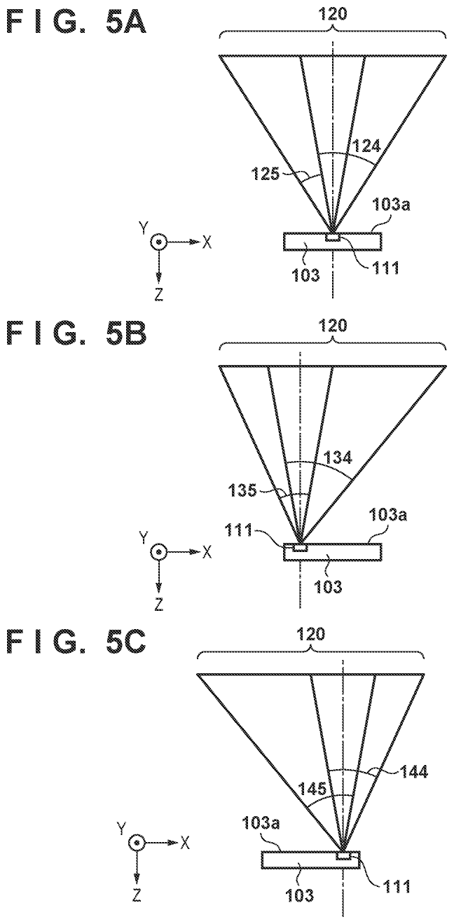

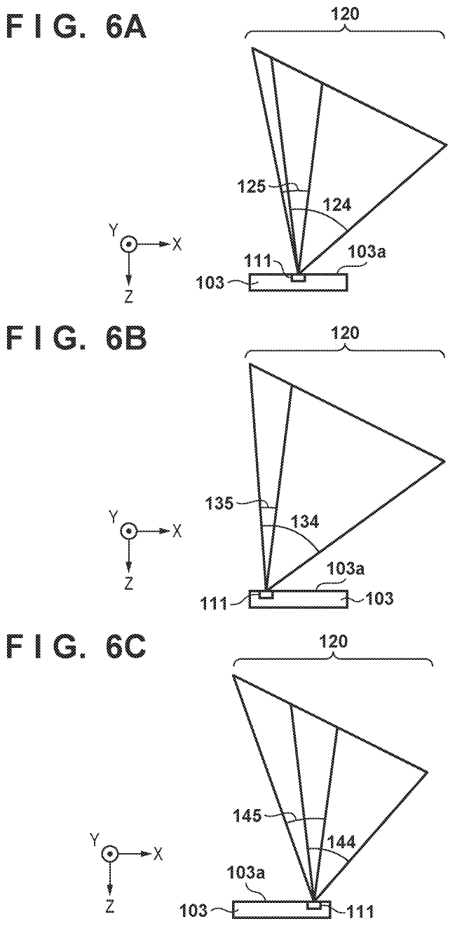

FIGS. 5A to 5C and FIGS. 6A to 6C are diagrams schematically showing a light beam incident on the first photoelectric conversion unit 112 and a light beam incident on the second photoelectric conversion unit 113 in a case where the tilt angle has been changed. FIGS. 5A to 5C show a case where the tilt angle is small, particularly, the tilt angle is 0 degrees. FIGS. 6A to 6C show a case where the tilt angle is large. Furthermore, FIG. 5A and FIG. 6A show the phase-difference detection pixel 111 located in a central region of the solid-state image sensor 103. Similarly, FIG. 5B and FIG. 6B show the phase-difference detection pixel 111 located in a periphery region in the −X direction, and FIG. 5C and FIG. 6C show the phase-difference detection pixel 111 located in a periphery region in the +X direction.

### <Case Where Tilt Angle is Small>

First, a description is given of a case where the tilt angle is 0 degrees as in FIGS. 5A to 5C. As in FIG. 5A, the positional relationship between light beams 124 and 125 that are respectively incident on the first photoelectric conversion unit 112 and the second photoelectric conversion unit 113 of the phase-difference detection pixel 111 located in the central region of the image plane 103a is line symmetry relative to the center of the exit pupil of the imaging optical system 101. Therefore, the first photoelectric conversion unit 112 and the second photoelectric conversion unit 113 of the phase-difference detection pixel 111 located in the central region of the image plane 103a have the same sensitivity.

In a case where the exit pupil distance of the imaging optical system 101 is infinite, the first photoelectric conversion unit 112 and the second photoelectric conversion unit 113 of a phase-difference detection pixel in a periphery region outside the central region of the solid-state image sensor 103 have the same sensitivity. However, due to, for example, a general demand for size reduction in an imaging optical system, the exit pupil distance is often a limited distance. In view of this, FIGS. 5B and 5C show a case where the exit pupil distance is a limited distance.

As apparent from FIG. 5B, in the phase-difference detection pixel 111 that is displaced in position in the −X direction on the image plane 103a, a light beam 134 incident on the first photoelectric conversion unit 112 is greater than a light beam 135 incident on the second photoelectric conversion unit 113. That is to say, in the phase-difference detection pixel 111 located in a periphery region in the −X direction on the image plane 103a, the sensitivity of the first photoelectric conversion unit 112 is higher than the sensitivity of the second photoelectric conversion unit 113.

Similarly, as apparent from FIG. 5C, in the phase-difference detection pixel 111 that is displaced in position in the +X direction on the image plane 103a, a light beam 145 incident on the second photoelectric conversion unit 113 is greater than a light beam 144 incident on the first photoelectric conversion unit 112. That is to say, in the phase-difference detection pixel 111 located in a periphery region in the +X direction on the image plane 103a, the sensitivity of the second photoelectric conversion unit 113 is higher than the sensitivity of the first photoelectric conversion unit 112.

### <Case Where Tilt Angle is Large>

Next, a description is given of a case where the tilt angle is large. In a case where the tilt angle is large, the exit pupil 120 of the imaging optical system 101 is inclined relative to the image plane 103a. Therefore, as shown in FIG. 6A, the first photoelectric conversion unit 112 and the second photoelectric conversion unit 113 have different sensitivities even in the phase-difference detection pixel 111 located in the central region of the image plane 103a. Specifically, the sensitivity of the first photoelectric conversion unit 112 located in the −X direction is higher than the sensitivity of the second photoelectric conversion unit 113 located in the +X direction.

The phase-difference detection pixel 111 that is displaced in the −X direction on the image plane 103a is located farther from the center of the exit pupil than the phase-difference detection pixel 111 in the central region is. Therefore, as shown in FIG. 6B, the sensitivity difference between the first photoelectric conversion unit and the second photoelectric conversion unit further increases compared to the central region. That is to say, the sensitivity of the first photoelectric conversion unit 112 is higher than the sensitivity of the second photoelectric conversion unit 113 in the phase-difference detection pixel 111 in a region that is displaced in the −X direction on the image plane 103a.

On the other hand, as shown in FIG. 6C, the phase-difference detection pixel 111 that is displaced in the +X direction on the image plane 103a is located closer to the center of the exit pupil than the phase-difference detection pixel 111 in the central region is. Therefore, the sensitivity difference between the first photoelectric conversion unit and the second photoelectric conversion unit is determined by the exit pupil distance of the imaging optical system and the tilt angle. In a case where the exit pupil distance is sufficiently long and the tilt angle is large, the sensitivity of the first photoelectric conversion unit 112 is higher than the sensitivity of the second photoelectric conversion unit 113 in the phase-difference detection pixel 111 that is displaced in the +X direction on the image plane 103a as in FIG. 6C. On the other hand, in a case where the exit pupil distance is short and the tilt angle is not large, the second photoelectric conversion unit 113 has a higher sensitivity than the first photoelectric conversion unit 112 does.

### <Summary>

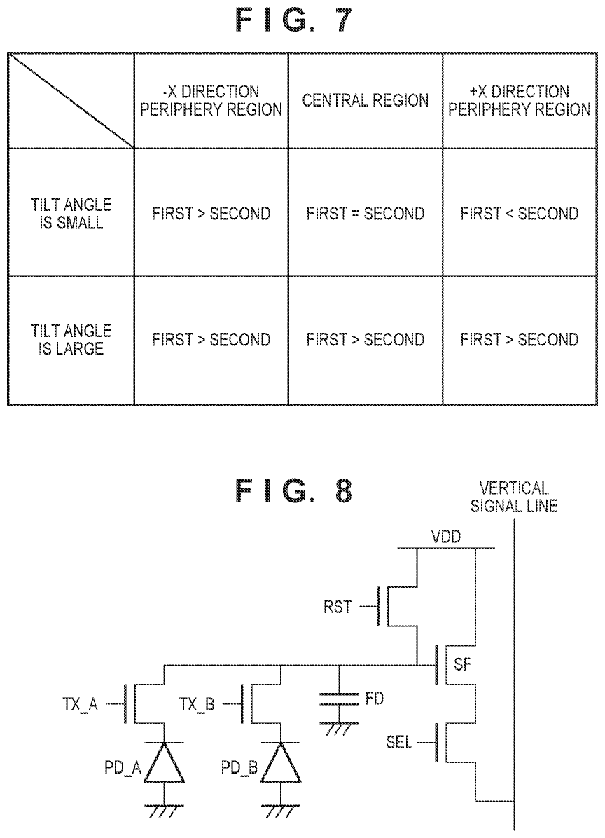

To summarize the above, in a case where tilt shooting has been performed on the image capturing apparatus that uses the solid-state image sensor 103 including the phase-difference detection pixels 111, the magnitude relationship between the sensitivities of the first photoelectric conversion unit and the second photoelectric conversion unit in a phase-difference detection pixel varies depending on the magnitude of the tilt angle and the position of the image plane 103a. A table of FIG. 7 shows a summary of the aforementioned relationships.

In FIG. 7, “first>second” indicates that the first photoelectric conversion unit 112 has a higher sensitivity than the second photoelectric conversion unit 113. Similarly, “first<second” means that the second photoelectric conversion unit 113 has a higher sensitivity than the first photoelectric conversion unit 112, and “first=second” means that the first photoelectric conversion unit 112 and the second photoelectric conversion unit 113 have the same sensitivity.

In the image capturing apparatus according to the present embodiment, in order to suppress a decrease in the accuracy of ranging that occurs due to the sensitivity difference between the first photoelectric conversion unit and the second photoelectric conversion unit, the order of readout from the first photoelectric conversion unit and the second photoelectric conversion unit is changed in accordance with the tilt angle. The following describes readout of pixel signals and the advantageous effects of the present embodiment.

### <Pixel Circuit>

FIG. 8 is a diagram showing an equivalent circuit diagram of a phase-difference detection pixel 111 inside the solid-state image sensor 103. The phase-difference detection pixel includes a first photoelectric conversion unit (PD_A), a second photoelectric conversion unit (PD_B), a first transfer transistor (TX_A), and a second transfer transistor (TX_B), and PD_A and PD_B share a floating diffusion (FD) region. Furthermore, with respect to the shared FD region, the phase-difference detection pixel includes a reset transistor (RST), a selection transistor (SEL), and a source follower unit (SF) that converts charges accumulated in the FD region into a voltage signal and reads out the voltage signal. The timings of TX_A, TX_B, RST, and SEL are controlled from peripheral circuits inside the solid-state image sensor 103 via a horizontal control line that extends in the row direction. Furthermore, SF is connected to a vertical signal line, and the readout unit 161 transmits the pixel signals obtained by the respective photoelectric conversion units to the signal processing unit 106. This readout unit 161 reads out the signals of the photoelectric conversion units in the order that conforms with the control performed by the main control unit 105.

### <Timing Chart and Summation Readout>

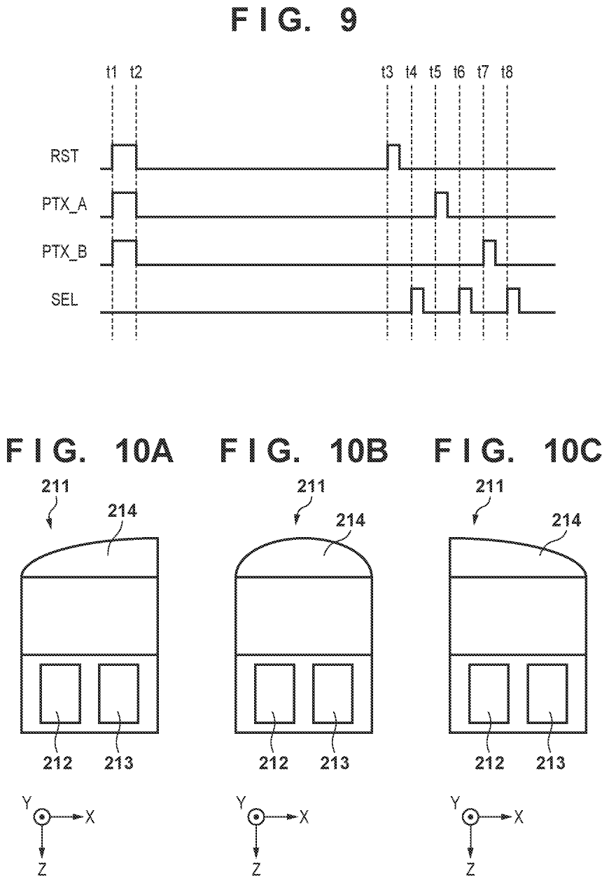

FIG. 9 is a diagram for describing a timing chart of the time when the readout unit 161 reads out pixel signals from a phase-difference detection pixel 111. First, at time t1, RST, TX_A, and TX_B are turned ON, thereby resetting the potentials of PD_A, PD_B, and FD region. At time t2, RST, TX_A, and TX_B are turned OFF, and accumulation of charges in PD_A and PD_B is started. Pixel signals of PD_A and PD_B are read out after a predetermined accumulation period has elapsed since the start of the accumulation of charges.

In the image capturing apparatus of the present embodiment, a pixel signal S1 obtained in one of the photoelectric conversion units, as well as a sum S1+2 of the pixel signals obtained in both of the photoelectric conversion units, is read out. Then, a pixel signal S2 of the other photoelectric conversion unit is obtained by subtracting S1 from S1+2; that is to say, so-called summation readout is used. Although the following describes a case where a signal of PD_A is read out first as an example, it is sufficient to interchange A and B in a case where a signal of PD_B is read out first. It is sufficient to prepare, as peripheral circuits for interchanging A and B, two types of vertical scanning circuits for which the timings of TX_A and TX_B have been interchanged, and to change the vertical scanning circuit to connect to in accordance with a column.

First, after RST is turned ON at time t3, SEL is turned ON at time t4; in this way, a noise level is read out. Subsequently, TX_A is turned ON at time t5, and SEL is turned ON at time t6; in this way, a pixel signal of the photoelectric conversion unit PD_A is obtained. Finally, TX_B is turned ON at time t7, and SEL is turned ON at time t8; in this way, a sum of an image signal of the photoelectric conversion unit PD_A and an image signal of PD_B is obtained.

### <Order of Signal Readout and Accuracy of Ranging>

A description is now given of noise carried by a pixel signal that is read out from the solid-state image sensor 103. Noise that is dominant as noise components includes optical shot noise Ns and readout circuit noise Nr. The optical shot noise occurs at the time of photoelectric conversion, and the magnitude thereof depends on the magnitude of a signal and is the square root of a signal amount. On the other hand, the readout circuit noise Nr occurs when a pixel signal is read out from FD region via SF, does not depend on the magnitude of the signal, and takes a constant value. As the optical shot noise and the readout circuit noise are independent events, the value of the sum of the noises is the root sum square.

Therefore, the signal-to-noise ratio SN1 of the pixel signal S1 that has been read out first is indicated by expression (1), and the signal-to-noise ratio SN1+2 of a summed signal S1+2 is indicated by expression (2).

$$\begin{matrix}[ Math . 1 ] & \\ S {N}_{1} = \frac{{S}_{1}}{\sqrt{{S}_{1} + {N}_{R}^{2}}} & ( 1 )\end{matrix}$$

$$\begin{matrix}[ Math . 2 ] & \\ {SN}_{1 + 2} = \frac{{S}_{1 + 2}}{\sqrt{{S}_{1 + 2} + {N}_{R}^{2}}} & ( 2 )\end{matrix}$$

On the other hand, the signal-to-noise ratio SN2 of the pixel signal S2, which is obtained by subtracting the pixel signal S1 from the summed signal S1+2, is indicated by expression (3) as noise attributed to read signals is added thereto.

$$\begin{matrix}[ Math . 3 ] & \\ S {N}_{2} = \frac{{S}_{1 + 2} - {S}_{1}}{\sqrt{{S}_{1 + 2} - {S}_{1} + 2 {N}_{R}^{2}}} & ( 3 )\end{matrix}$$

As can be understood from comparison between expression 1 and expression 3, in a case where the magnitudes of S1 and S2 are the same, the signal-to-noise ratio of the pixel signal is lower in the photoelectric conversion unit from which the pixel signal has been read out later than in the photoelectric conversion unit from which the pixel signal has been read out first.

<Read from Unit with Low Sensitivity First>

As stated earlier, in order to suppress a decrease in the accuracy of ranging that occurs due to a sensitivity difference between the first photoelectric conversion unit and the second photoelectric conversion unit, the image capturing apparatus of the present embodiment changes the order of readout from the first photoelectric conversion unit and the second photoelectric conversion unit in accordance with a tilt angle. Specifically, the main control unit 105 controls the readout unit 161 to read out a pixel signal from the photoelectric conversion unit with a low sensitivity first, and read out a pixel signal from the photoelectric conversion unit with a high sensitivity later. The following describes the reason why a decrease in the accuracy of ranging can be suppressed.

First, the following is a discussion of a case where a pixel signal from the photoelectric conversion unit with a high sensitivity is read out first, and a pixel signal from the photoelectric conversion unit with a low sensitivity is read out later. As stated earlier, in a case where the same amount of light is incident on the photoelectric conversion units, the signal-to-noise ratio of the pixel signal is lower in the photoelectric conversion unit from which the pixel signal has been read out later than in the photoelectric conversion unit from which the pixel signal has been read out first.

That is to say, in a case where the pixel signal from the photoelectric conversion unit with a high sensitivity is read out first and the pixel signal from the photoelectric conversion unit with a low sensitivity is read out later, the magnitude of the signal is smaller in the latter, and noise is worse in the latter as well. As the accuracy of detection of an image displacement amount is mainly determined based on the pixel signal that is assumed to have a lower signal-to-noise ratio, the accuracy of ranging decreases in a case where the pixel signal from the photoelectric conversion unit with a low sensitivity is read out later.

On the other hand, in a case where the pixel signal from the photoelectric conversion unit with a low sensitivity is read out first and the pixel signal from the photoelectric conversion unit with a high sensitivity is read out later, the magnitude of the signal is smaller in the former, but noise characteristics are more favorable in the former. Therefore, a decrease in the accuracy of ranging can be suppressed in a case where the pixel signal from the photoelectric conversion unit with a low sensitivity is read out first and the pixel signal from the photoelectric conversion unit with a high sensitivity is read out later, compared to a case where the pixel signal from the photoelectric conversion unit with a high sensitivity is read out first and the pixel signal from the photoelectric conversion unit with a low sensitivity is read out later.

<Making Change in Accordance with Magnitudes of Pixel Signals>

Note that as the difference between expression 2 and expression 3 is the readout noise, a pixel signal of either photoelectric conversion unit may be read out first in a case where the optical shot noise is sufficiently larger than the readout noise. That is to say, whether to designate the order of readout of pixel signals from the photoelectric conversion units may be changed in accordance with the magnitudes of pixel signals.

### <Order of Readout in Case Where Tilt Angle is Small>

As shown in FIG. 7, in a case where the tilt angle is small (a case where the tilt angle is equal to or smaller than a preset threshold), the order of readout from the first photoelectric conversion unit and the second photoelectric conversion unit can be changed in accordance with the position of a phase-difference detection pixel on the image plane. Specifically, relative to a line that passes through the center of the solid-state image sensor 103 and is perpendicular to the direction connecting the center of the first photoelectric conversion unit and the center of the second photoelectric conversion unit (the pupil-division direction), readout from the second photoelectric conversion unit is performed first in a region in the −X direction, whereas readout from the first photoelectric conversion unit is performed first in a region in the +X direction. That is to say, in one embodiment, a line that passes through the center of the solid-state image sensor and is perpendicular to the pupil-division direction is used as a border at which the order of readout from the first photoelectric conversion unit and the second photoelectric conversion unit is reversed.

Note that as can be understood from FIG. 5A, the sensitivity difference between the first photoelectric conversion unit and the second photoelectric conversion unit is small in the central region of the solid-state image sensor. Therefore, in the central region of the solid-state image sensor, readout from either the first photoelectric conversion unit or the second photoelectric conversion unit may be performed first. That is to say, it is sufficient that readout from the first photoelectric conversion unit and the second photoelectric conversion unit be performed in opposite orders in regions that are distanced, by a first threshold or more, from the line that passes through the center of the solid-state image sensor and is perpendicular to the pupil-division direction.

### <Order of Readout in Case Where Tilt Angle is Large>

As shown in FIG. 7, in a case where the tilt angle is large (a case where the tilt angle is larger than the threshold), the sensitivity of the first photoelectric conversion unit is higher irrespective of the phase-difference detection pixels on the image plane. Therefore, a pixel signal from the second photoelectric conversion unit can be read out first. That is to say, in a case where the tilt angle is large, a signal can be read out first from the photoelectric conversion unit that is located on the side where the distance from the image plane to the subject plane is relatively short (the +X direction).

<Moving Borderline in Accordance with Tilt Angle>

The larger the tilt angle, the greater the inclination of the exit pupil. Therefore, the borderline at which the order of readout from the first photoelectric conversion unit and the second photoelectric conversion unit is reversed is set so that the borderline extends in the direction perpendicular to the pupil-division direction, and the borderline shifts toward the side where the distance from the image plane to the subject plane is relatively short as the tilt angle increases.

### <Making Designation in Stepwise Manner>

The borderline at which the order of readout from the first photoelectric conversion unit and the second photoelectric conversion unit is reversed may move continuously in accordance with the tilt angle. This configuration increases the proportion of pixels in which a pixel signal from the photoelectric conversion unit with a low sensitivity is read out first, and improves the accuracy of ranging. It should be noted that the borderline may be changed in a stepwise manner. For example, the order of readout may be changed depending on whether the tilt angle is equal to or larger than a second threshold or is smaller than the second threshold.

<Designating Pixels Associated with First Readout Only in Case Where Tilt Angle is Large>

Furthermore, as can be understood from comparison between FIGS. 5A to 5C and FIGS. 6A to 6C, the sensitivity difference between the first photoelectric conversion unit and the second photoelectric conversion unit is large particularly in a periphery region in which the tilt angle is large and which is on the side where the distance from the image plane to the subject plane is relatively long (the −X direction). In view of this, the order of readout from the photoelectric conversion units may be designated only in a case where the tilt angle is larger than the second threshold. Furthermore, the order of readout from the photoelectric conversion units may be designated only with respect to the phase-difference detection pixels in a periphery region on the side where the distance from the image plane to the subject plane is relatively long (the −X direction).

Note that although the foregoing has described a case where a phase-difference detection pixel includes two photoelectric conversion units, it may include three or more photoelectric conversion units. In this case, a pixel signal of the photoelectric conversion unit with the lowest sensitivity may be read out first, and then pixel signals may be read out in sequence in ascending order of sensitivity.

### Second Embodiment

A second embodiment is now described. The present second embodiment pertains to a structure of the solid-state image sensor according to the first embodiment. The solid-state image sensor according to the present second embodiment is given reference sign 203, and an image plane thereof is denoted by 203a. As other constituents are the same as those of the first embodiment, they will be described using the same reference signs thereas.

FIGS. 10A to 10C are structural diagrams of the phase-difference detection pixels 211 in the solid-state image sensor 203 according to the second embodiment. One phase-difference detection pixel 211 according to the present second embodiment includes a first photoelectric conversion unit 212 located on the left side of the image plane 203a (the −X direction), a second photoelectric conversion unit 213 located on the right side thereof (the +X direction), and a microlens 214, similarly to the phase-difference detection pixels 111 according to the first embodiment. Also, the microlenses 214 of the phase-difference detection pixels 211 according to the present second embodiment are structured in such a manner that they are decentered in accordance with the positions thereof from the center of the image plane 203a.

Specifically, as shown in FIG. 10A, the microlens 214 of the phase-difference detection pixel 211 located at a position that is displaced in the −X direction on the image plane 203a is decentered in the +X direction relative to the center of this pixel. Also, as shown in FIG. 10C, the microlens 214 of the phase-difference detection pixel 211 located at a position that is displaced in the +X direction on the image plane 203a is decentered in the −X direction relative to the center of this pixel. Furthermore, as shown in FIG. 10B, the microlens 214 of the phase-difference detection pixel 231 located in a central region of the image plane 203a is not decentered relative to the center of this pixel. By adopting such a configuration, the sensitivity difference between the first photoelectric conversion unit and the second photoelectric conversion unit in the phase-difference detection pixels in a periphery region can be reduced in a case where the exit pupil distance of the imaging optical system is short.

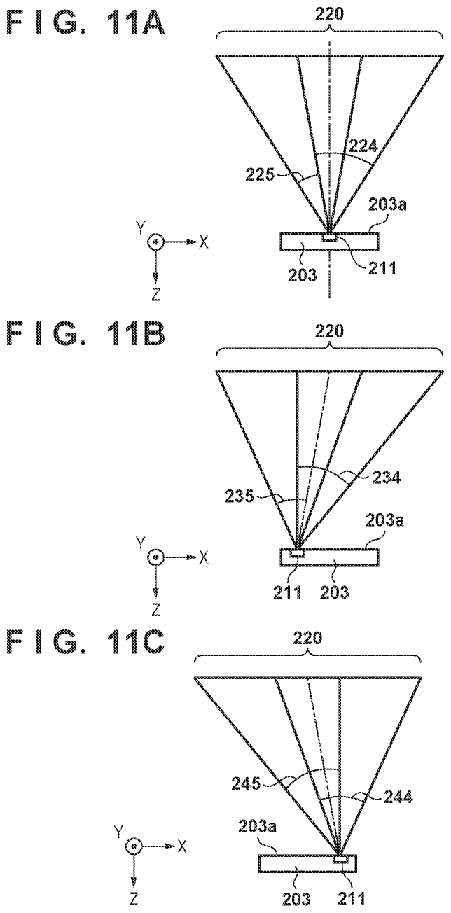

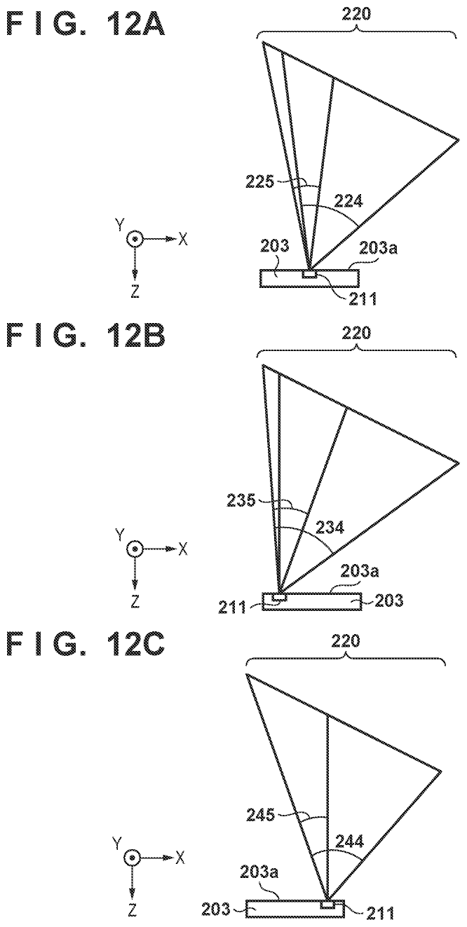

FIGS. 11A to 11C and FIGS. 12A to 12C are diagrams schematically showing a light beam incident on the first photoelectric conversion unit 212 and a light beam incident on the second photoelectric conversion unit 213 in a case where the tilt angle has been changed. FIGS. 11A to 11C show a case where the tilt angle is small, particularly, the tilt angle is 0 degrees, whereas FIGS. 12A to 12C show a case where the tilt angle is large. Also, FIG. 11A and FIG. 12A both show a case where the phase-difference detection pixel 211 is located in the central region of the image plane 203a. Similarly, FIG. 11B and FIG. 12B both show a case where the phase-difference detection pixel 211 is located at a position that is displaced in the −X direction on the image plane 203a. Furthermore, FIG. 11C and FIG. 12C both show a case where the phase-difference detection pixel 211 is located at a position that is displaced in the +X direction on the image plane 203a.

In the image capturing apparatus according to the second embodiment, the microlenses of the phase-difference detection pixels 211 are decentered in accordance with the exit pupil 220 of the imaging optical system 101. Therefore, in a case where the tilt angle is 0 degrees as in FIGS. 11A to 11C, the first photoelectric conversion unit and the second photoelectric conversion unit have the same sensitivity both in the central region and in the periphery regions. However, in a case where the tilt angle is large, the center of the exit pupil of the imaging optical system is displaced from the center of the solid-state image sensor toward the side where the distance from the image plane to the subject plane is relatively close (the +X direction). Therefore, in a case where the tilt angle is large as in FIGS. 12A to 12C, the first photoelectric conversion unit has a higher sensitivity than the second photoelectric conversion unit.

As described above, even in a case where the structures of the phase-difference detection pixels have been optimized in accordance with the exit pupil of the imaging optical system, when tilt shooting has been performed, the magnitude relationship between the sensitivities of the first photoelectric conversion unit and the second photoelectric conversion unit in a phase-difference detection pixel varies depending on the tilt angle. For this reason, in the image capturing apparatus according to the second embodiment as well, in order to suppress a decrease in the accuracy of ranging that occurs due to the sensitivity difference between the first photoelectric conversion unit and the second photoelectric conversion unit, the order of readout from the first photoelectric conversion unit and the second photoelectric conversion unit is changed in accordance with the tilt angle. Specifically, in a case where the tilt angle is larger than a preset threshold, a decrease in the accuracy of ranging is suppressed by reading out a pixel signal from the second photoelectric conversion unit first.

### Summary of Second Embodiment

As described above, in the image capturing apparatus according to the second embodiment, the amounts of decentering of the microlenses in the phase-difference detection pixels are adjusted so that the first photoelectric conversion unit and the second photoelectric conversion unit have the same sensitivity in the case of a first tilt angle. Also, the image capturing apparatus is configured so that, in a case where the tilt angle is equal to or larger than a second tilt angle that is larger than the first tilt angle, a signal from the photoelectric conversion unit located on the side where the distance from the image plane to the subject plane is relatively close (the +X direction) is read out first.

### Third Embodiment

A third embodiment is now described. The present third embodiment pertains to a structure of the solid-state image sensor according to the first embodiment. The solid-state image sensor according to the present third embodiment is given reference sign 303, and an image plane thereof is denoted by 303a. As other constituents are the same as those of the first embodiment, they will be described using the same reference signs thereas.

The present third embodiment is an example in which the microlenses of the phase-difference detection pixels 311 in the solid-state image sensor 303 have been optimized in line with a case where the tilt angle is large.

Specifically, in the present third embodiment, each of the microlenses of the phase-difference detection pixels 311 in every region of the solid-state image sensor 303 is decentered in the +X direction relative to the center of the pixel thereof. Also, the amounts of decentering of the microlenses change either continuously, or in a stepwise manner, so that they become the largest in a periphery region in the −X direction, and the smallest in a periphery region in the +X direction. By adopting such a configuration, the sensitivity difference between the first photoelectric conversion unit and the second photoelectric conversion unit can be reduced in a case where the tilt angle is large.

Note that with regard to one phase detection pixel according to the present third embodiment, the −X side on the image plane 303a is referred to as a first photoelectric conversion unit, and the +X side is referred to as a second photoelectric conversion unit, similarly to the first and second embodiments.

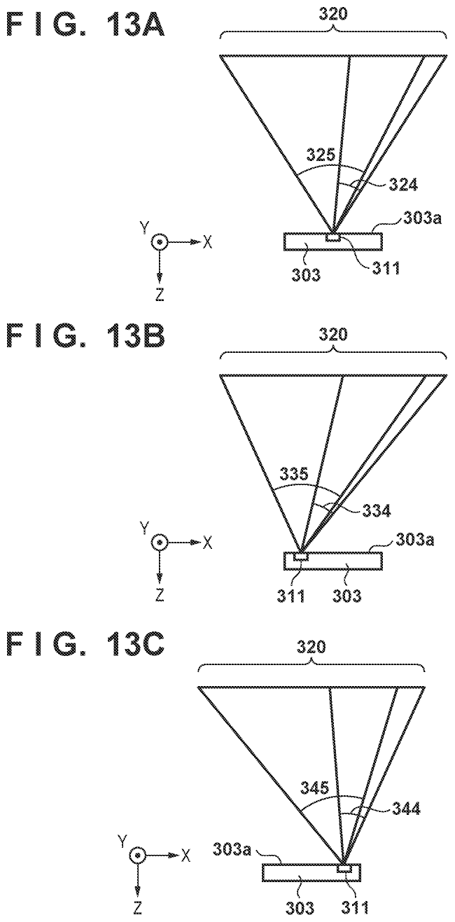

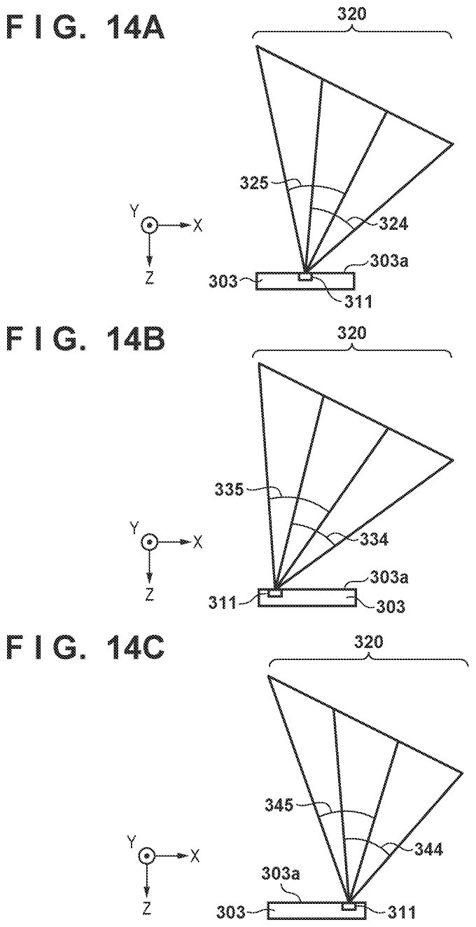

FIGS. 13A to 13C and FIGS. 14A to 14C schematically show a light beam incident on the first photoelectric conversion unit 312 and a light beam incident on the second photoelectric conversion unit 313 in a case where the tilt angle has been changed.

FIGS. 13A to 13C show a case where the tilt angle is small, particularly, the tilt angle is 0 degrees, whereas FIGS. 14A to 14C show a case where the tilt angle is large. Also, FIG. 13A and FIG. 14A both show light beams incident on the first and second photoelectric conversion units of a phase-difference detection pixel 311 located in the central region of the image plane 303a. Similarly, FIG. 13B and FIG. 14B show light beams incident on the first and second photoelectric conversion units of a phase-difference detection pixel 311 located at a position that is displaced in the −X direction on the image plane 303a, and FIG. 13C and FIG. 14C show light beams incident on the first and second photoelectric conversion units of a phase-difference detection pixel 311 located at a position that is displaced in the +X direction on the image plane 303a.

In the image capturing apparatus according to the present third embodiment, the microlenses of the phase-difference detection pixels 311 are decentered in accordance with the exit pupil 320 of the imaging optical system in a case where the tilt angle is large. Therefore, in a case where the tilt angle is large as in FIGS. 14A to 14C, the first photoelectric conversion unit and the second photoelectric conversion unit have the same sensitivity both in the central region and in the periphery regions. However, in a case where the tilt angle is small as in FIGS. 13A to 13C, the second photoelectric conversion unit has a higher sensitivity than the first photoelectric conversion unit.

As described above, even in a case where the structures of the phase-difference detection pixels have been optimized in line with a case where the tilt angle is large, the magnitude relationship between the sensitivities of the first photoelectric conversion unit and the second photoelectric conversion unit in a phase-difference detection pixel varies depending on the tilt angle. For this reason, in the image capturing apparatus according to the third embodiment as well, in order to suppress a decrease in the accuracy of ranging that occurs due to the sensitivity difference between the first photoelectric conversion unit and the second photoelectric conversion unit, the order of readout from the first photoelectric conversion unit and the second photoelectric conversion unit is changed in accordance with the tilt angle. Specifically, in a case where the tilt angle is small, a decrease in the accuracy of ranging can be suppressed by reading out a pixel signal from the first photoelectric conversion unit first.

### Summary of Configuration of Third Embodiment

In the image capturing apparatus according to the third embodiment, the amounts of decentering of the microlenses in the phase-difference detection pixels are adjusted so that the first photoelectric conversion unit and the second photoelectric conversion unit have the same sensitivity in the case of a third tilt angle. Also, the image capturing apparatus is configured so that, in a case where the tilt angle is smaller than a fourth tilt angle that is smaller than the third tilt angle, a signal from the photoelectric conversion unit located on the side where the distance from the image plane to the subject plane is relatively long (the −X direction) is read out first.

### Fourth Embodiment

As has been described in the second and third embodiments, the position of the exit pupil of the imaging optical system 101 varies depending on the tilt angle. Therefore, the amounts of decentering of the microlenses can be optimized in relation to an intermediate tilt angle. The image capturing apparatus according to a fourth embodiment is an example in which the amounts of decentering of the microlenses have been optimized in relation to an angle that is exactly a midpoint between the smallest tilt angle and the largest tilt angle that have been preset for the case of tilt shooting.

In the case of the image capturing apparatus according to the fourth embodiment as well, the magnitude relationship between sensitivities varies depending on the tilt angle and the position of a phase-difference detection pixel on the image plane, and therefore the order of readout from the photoelectric conversion units can be changed depending on them. Specifically, the proportion of the phase-difference detection pixels in which readout from the first photoelectric conversion unit is performed first is increased as the tilt angle decreases, and the proportion of the phase-difference detection pixels in which readout from the second photoelectric conversion unit is performed first is increased as the tilt angle increases. In this way, a decrease in the accuracy of ranging that occurs due to the sensitivity difference between the photoelectric conversion units can be suppressed.

### Fifth Embodiment

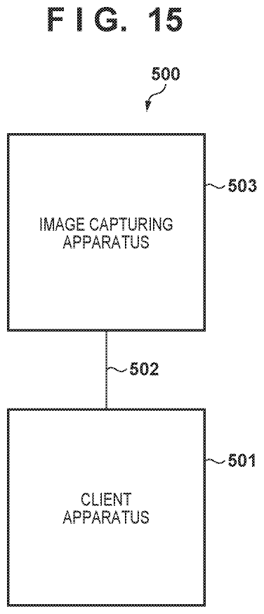

A fifth embodiment is now described. The following describes a surveillance system that uses the image capturing apparatus described in the above first to fourth embodiments. FIG. 15 is a configuration diagram of a surveillance system 500 that uses an image capturing apparatus 503 according to any one of the first to fourth embodiments. The image capturing apparatus 503 and a client apparatus 501 are connected in a state where they can mutually communicate with each other via a network 502. The client apparatus 501 transmits various types of commands for controlling the image capturing apparatus 503. In response, the image capturing apparatus 503 transmits responses to the commands and captured image data to the client apparatus 501. Whether to drive the image capturing apparatus 503 in a depth-of-field priority mode can be selected by a user via the client apparatus 501.

The client apparatus 501 is, for example, an external device such as a PC, and the network 502 is composed of a wired LAN, a wireless LAN, or the like. Furthermore, it is permissible to adopt a configuration in which power is supplied to the image capturing apparatus 503 via the network 502.

### OTHER EMBODIMENTS

Embodiment(s) of the disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-148405, filed Sep. 16, 2022, which is hereby incorporated by reference herein in its entirety.

What is claimed is:

1. An apparatus provided with a sensor including a plurality of pixels that are arrayed two-dimensionally, at least a part of the plurality of pixels being a phase-difference detection pixel that include a first conversion unit and a second conversion unit for performing phase-difference AF, the apparatus comprising:
a driving mechanism configured to change an angle of an image plane of the sensor relative to a main plane of an optical system; and
a readout unit configured to read out signals obtained in the first conversion unit and the second conversion unit in an order corresponding to the angle.

2. The apparatus according to claim 1, wherein
the readout unit is further configured to first read out a signal from one of the first conversion unit and the second conversion unit, and then read out a sum of signals of the first conversion unit and the second conversion unit.

3. The apparatus according to claim 2, wherein
the readout unit is further configured to perform readout first from one of the first conversion unit and the second conversion unit that has a lower sensitivity than the other one.

4. The apparatus according to claim 1, wherein
the readout unit is further configured to change an order of readout from the first conversion unit and the second conversion unit depending on magnitudes of pixel signals.

5. The apparatus according to claim 1, wherein
provided that both side regions that are distanced by a first threshold or more in a direction that passes through a center of the sensor and is perpendicular to a pupil-division direction are a first region and a second region, the readout unit is further configured to read out the signals so that an order of readout from the first and second conversion units in the second region is a reverse of an order of readout from the first and second conversion units in the first region.

6. The apparatus according to claim 5, wherein
with regard to two regions that border each other along a line that passes through the center of the sensor and is perpendicular to the pupil-division direction, an order of readout from the first and second conversion units in one of the two regions is a reverse of an order of readout from the first and second conversion units in the other region.

7. The apparatus according to claim 6, wherein
a borderline that defines the regions in which readout from the first conversion unit and the second conversion unit is performed in opposite orders extends in a direction perpendicular to the pupil-division direction, and a position of the borderline shifts toward a side where a distance from the image plane to a subject plane becomes shorter as the angle increases.

8. The apparatus according to claim 1, wherein
the readout unit is further configured to change an order of readout from the first and second conversion units depending on whether the angle is equal to or larger than a second threshold.

9. The apparatus according to claim 1, further comprising a setting unit configured to, only in a case where the angle is equal to or larger than a second threshold, set a setting indicating one of the first and second conversion units from which readout is performed first by the readout unit.

10. The apparatus according to claim 9, wherein
the setting unit is further configured to, only with respect to phase-difference detection pixels in a periphery region on a side where a distance from the image plane to a subject plane is relatively long, configure the setting indicating one of the first and second conversion units from which readout is performed first by the readout unit.

11. The apparatus according to claim 1, wherein
the phase-difference detection pixels include microlenses, and
a center of the microlens of each phase-difference detection pixel is decentered in accordance with a position of the sensor.

12. The apparatus according to claim 11, wherein
the readout unit is further configured to
read out the signals without changing an order of readout from the first and second conversion units in a case where the angle is equal to or smaller than a preset first angle, and
read out the signal first from the conversion unit located on a side where a distance from the image plane to a subject plane is relatively short in a case where the angle exceeds the first angle.

13. The apparatus according to claim 11, wherein
the microlenses are placed in a decentered manner so that the first conversion unit and the second conversion unit have the same sensitivity in a case where the angle is a preset second angle, and
the readout unit is further configured to, in a case where the angle is smaller than the second angle, read out the signal first from the conversion unit located on a side where a distance from the image plane to a subject plane is relatively long.

14. The apparatus according to claim 11, wherein
the microlenses are placed in a decentered manner so that the first conversion unit and the second conversion unit have the same sensitivity in a case of a middle angle between the largest angle and the smallest angle that can be set by the driving mechanism, and
a proportion of phase-difference detection pixels in which readout from the first conversion unit is performed first is larger in a case where the angle is smaller than the middle angle, and a proportion of phase-difference detection pixels in which readout from the second conversion unit is performed first is larger in a case where the angle is larger than the middle angle.

15. A method of controlling an apparatus provided with a sensor including a plurality of pixels that are arrayed two-dimensionally, at least a part of the plurality of pixels being a phase-difference detection pixel that include a first conversion unit and a second conversion unit for performing phase-difference AF and a driving mechanism configured to change an angle of an image plane of the sensor relative to a main plane of an optical system, the method comprising:
reading out signals obtained in the first conversion unit and the second conversion unit in an order corresponding to the angle.

16. The method according to claim 15, further comprising:
reading out a signal from one of the first conversion unit and the second conversion unit; and
reading out a sum of signals of the first conversion unit and the second conversion unit.

17. The method according to claim 15, further comprising:
changing an order of readout from the first conversion unit and the second conversion unit depending on magnitudes of pixel signals or on whether the angle is equal to or larger than a second threshold.

18. A non-transitory computer-readable medium storing one or more programs which, when executed by a computer comprising one or more processors and one or more memories, cause the computer to control an apparatus provided with a sensor including a plurality of pixels that are arrayed two-dimensionally, at least a part of the plurality of pixels being a phase-difference detection pixel that include a first conversion unit and a second conversion unit for performing phase-difference AF and a driving mechanism configured to change an angle of an image plane of the sensor relative to a main plane of an optical system, wherein the one or more programs further cause the computer to
read out signals obtained in the first conversion unit and the second conversion unit in an order corresponding to the angle.

19. The non-transitory computer-readable medium according to claim 18, further comprising:
reading out a signal from one of the first conversion unit and the second conversion unit; and
reading out a sum of signals of the first conversion unit and the second conversion unit.

20. The non-transitory computer-readable medium according to claim 18, further comprising:
changing an order of readout from the first conversion unit and the second conversion unit depending on magnitudes of pixel signals or on whether the angle is equal to or larger than a second threshold.
